(19) United States
(12) Patent Application Publication
(10) Pub. No.: US 2025/0392845 A1
(43) Pub. Date: Dec. 25, 2025

(54) STACKED IMAGE SENSOR

(71) Applicant: Samsung Electronics Co., Ltd., Suwon-si (KR)

(72) Inventors: Seungjoon LEE, Suwon-si (KR); Jaesang YOO, Suwon-si (KR); Jeongki KIM, Suwon-si (KR); Chungho SONG, Suwon-si (KR)

(73) Assignee: Samsung Electronics Co., Ltd., Suwon-si (KR)

(21) Appl. No.: 19/062,158

(22) Filed: Feb. 25, 2025

(30) Foreign Application Priority Data
Jun. 21, 2024 (KR) 10-2024-0081373

(51) Int. Cl. H04N 25/79; H04N 25/59; H04N 25/77; H10F 39/00

(52) U.S. Cl. CPC H04N 25/79; H04N 25/59; H04N 25/77; H10F 39/8037; H10F 39/809; H10F 39/811

(57) ABSTRACT

A stacked image sensor includes a first pixel array including a plurality of photoelectric conversion elements sharing a floating diffusion node, and a second pixel array configured to convert optical signals from the plurality of photoelectric conversion elements into electrical signals and output the electrical signals, the second pixel array including a first conversion gain control transistor connected to the floating diffusion node, and a second conversion gain control transistor connected to the first conversion gain control transistor in series, and the first pixel array further includes a capacitor connected between the first conversion gain control transistor and the second conversion gain control transistor.

### CROSS-REFERENCE TO RELATED APPLICATION

This application is based on and claims priority under 35 U.S.C. § 119 to Korean Patent Application No. 10-2024-0081373, filed on Jun. 21, 2024, in the Korean Intellectual Property Office, the disclosure of which is incorporated by reference herein in its entirety.

### BACKGROUND

The inventive concepts relate to stacked image sensors. More particularly, the inventive concepts relate to stacked image sensors operable in a multi-conversion gain mode.

An image sensor may be a device that converts an optical image into an electrical signal and may be used in a camera of a portable electronic device, such as a smartphone or a tablet personal computer (PC). Stacked image sensors have been developed to reduce the size of portable electronic devices and improve camera performance. The stacked image sensor may achieve a reduction in a planar area of an image sensor, an improvement in the resolution of the image sensor, and an increase in signal processing speed of the image sensor.

### SUMMARY

The inventive concepts provide image sensors capable of securing capacitance in a floating diffusion area by using a capacitor formed on a top plate.

According to some aspects of the inventive concepts, there is provided stacked image sensors.

According to some aspects of the inventive concepts, there is provided the stacked image sensor including a first pixel array including a plurality of photoelectric conversion elements sharing a floating diffusion node, and a second pixel array configured to convert optical signals from the plurality of photoelectric conversion elements into electrical signals and output the electrical signals, the second pixel array including a first conversion gain control transistor connected to the floating diffusion node, and a second conversion gain control transistor connected to the first conversion gain control transistor in series, and the first pixel array further includes a capacitor connected between the first conversion gain control transistor and the second conversion gain control transistor.

According to some aspects of the inventive concepts, there is provided a stacked image sensor.

According to some aspects of the inventive concepts, there is provided the stacked image sensor including a first semiconductor chip including at least one photoelectric conversion area, at least one floating diffusion area, at least one transfer transistor configured to transmit charges in the at least one photoelectric conversion area to the at least one floating diffusion area, and a deep trench isolation structure configured to separate each of the at least one photoelectric conversion area, and a second semiconductor chip including a pixel circuit, the pixel circuit being configured to convert an optical signal from the at least one photoelectric conversion area into an electrical signal and output the electrical signal, and the first semiconductor chip including a capacitor formed on the deep trench isolation structure and configured to adjust a conversion gain in the at least one floating diffusion area.

According to some aspects of the inventive concepts, there is provided a stacked image sensor.

According to some aspects of the inventive concepts, there is provided the stacked image sensor including a first unit pixel including a first pixel array and a second pixel array, the first pixel array comprising a plurality of photoelectric conversion elements sharing a floating diffusion node, and the second pixel array configured to convert optical signals from the plurality of photoelectric conversion elements into electrical signals and output the electrical signals, and a second unit pixel including a first pixel array and a second pixel array, the first pixel array of the second unit pixel comprising a plurality of photoelectric conversion elements sharing a floating diffusion node, and the second pixel array configured to convert optical signals from the plurality of photoelectric conversion elements into electrical signals and output the electrical signals, the first pixel array of the first unit pixel and the first pixel array of the second unit pixel are in a first semiconductor chip, and the second pixel array of the first unit pixel and the second pixel array of the second unit pixel are in a second semiconductor chip, the second pixel array of the first unit pixel and the second pixel array of the second unit pixel each include a first conversion gain control transistor connected to the floating diffusion node and a second conversion gain control transistor connected to the first conversion gain control transistor in series, and the first pixel array of the first unit pixel and the first pixel array of the second unit pixel each further include a capacitor configured to respectively adjust a conversion gain of the floating diffusion node.

### BRIEF DESCRIPTION OF THE DRAWINGS

Example embodiments of the inventive concepts will be more clearly understood from the following detailed description taken in conjunction with the accompanying drawings in which:

FIG. 1 is a block diagram of an image sensor according to some example embodiments;

FIG. 2 is a block diagram showing a first pixel array, a second pixel array, a logic circuit, and an analog digital converter (ADC) of FIG. 1;

FIG. 3 is a perspective view three-dimensionally showing the first pixel array, the second pixel array, the logic circuit, and the ADC of FIG. 1;

FIG. 4 is a circuit diagram showing a unit pixel including the first pixel array and the second pixel array of FIG. 1;

FIGS. 5A to 5C are timing diagrams showing timings of signals applied to adjust a multi-conversion gain in a circuit of FIG. 4;

FIGS. 6A and 6B are circuit diagrams of unit pixels according to some example embodiments;

FIG. 7A is a plan view showing an arrangement of components of a first pixel array on a first semiconductor chip in the circuit diagram of FIG. 4;

FIG. 7B is a cross-sectional view of the plan view of FIG. 7A, taken along a line A-A′ of FIG. 7A;

FIG. 8A is a plan view of unit pixels in a first semiconductor chip, according to some example embodiments;

FIG. 8B is a plan view of unit pixels in a second semiconductor chip, according to some example embodiments;

FIGS. 9A and 9B are cross-sectional views of examples of the plan view of FIG. 8A, taken along a line B-B′ of FIG. 8A; and

FIGS. 10A to 10F are cross-sectional views to explain the generation of a capacitor in a first semiconductor chip, according to some example embodiments.

### DETAILED DESCRIPTION

Hereinafter, one or more embodiments are described with reference to the attached drawings.

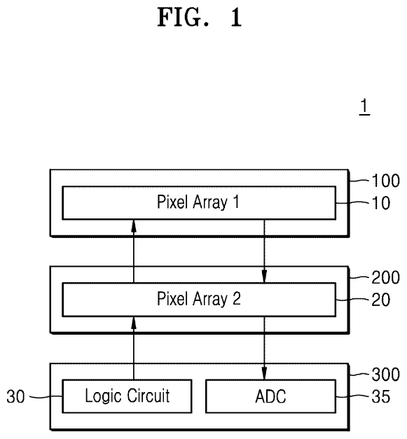

FIG. 1 is a block diagram of an image sensor according to some example embodiments.

Referring to FIG. 1, an image sensor 1 may include a first semiconductor chip 100, a second semiconductor chip 200, and a third semiconductor chip 300. The first semiconductor chip 100, the second semiconductor chip 200, and the third semiconductor chip 300 may overlap each other in a plan view. The first semiconductor chip 100, the second semiconductor chip 200, and the third semiconductor chip 300 may be sequentially stacked in a vertical direction. The first semiconductor chip 100 may be referred to as an upper plate, the second semiconductor chip 200 as a middle plate, and the third semiconductor chip 300 as a lower plate.

The first semiconductor chip 100 may include a first pixel array 10. The second semiconductor chip 200 may include a second pixel array 20. The third semiconductor chip 300 may include a logic circuit 30 and an analog digital converter (ADC) 35. The first pixel array 10 may generate charges in proportion to the amount of light entering the first pixel array 10. Although not shown, light may be concentrated through a microlens arranged on the first pixel array 10. The second pixel array 20 may convert an optical signal into an electrical signal, that is, an analog signal, according to the control by the logic circuit 30. The second pixel array 20 may output the analog signal to the ADC 35. The ADC 35 may convert the analog signal to a digital signal. The ADC 35 may provide data based on the digital signal.

Although not shown, an image sensor according to some example embodiments may further include a memory cell array. The memory cell array may store data based on the digital signal.

The data may be image data generated in units of frames. The number of bits in the data may be determined based on the resolution of the ADC 35. The number of bits in the data may be determined based on the high dynamic range (HDR) supported by the image sensor. Additionally, the bits in the data may further include at least one extended bit representing the location where data is generated, data information, and the like.

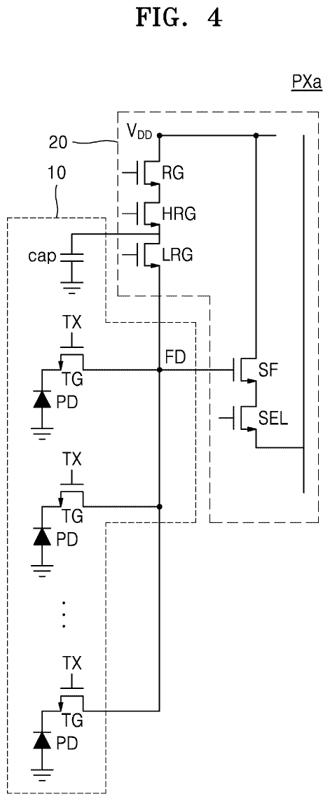

The image sensor 1 is described as a 3-stack image sensor that includes the first pixel array 10 and the second pixel array 20, both of which are formed on different chips. The image sensor 1 may perform a multi-conversion gain operation using a structure including a capacitor in the first pixel array 10 of the first semiconductor chip 100, which is described below in detail with reference to FIG. 4.

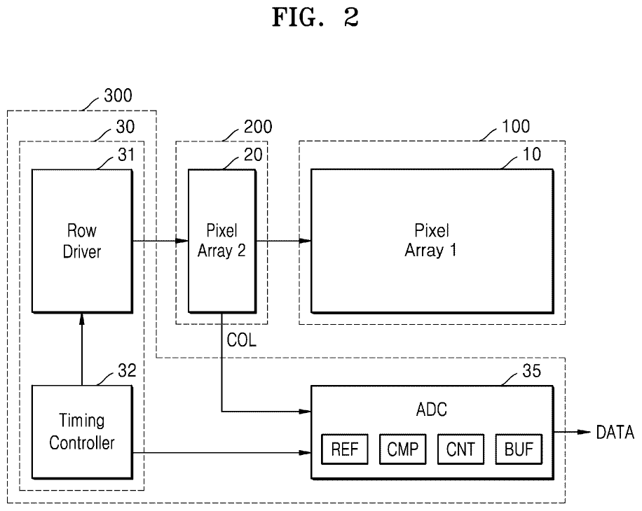

FIG. 2 is a block diagram showing the first pixel array 10, the second pixel array 20, the logic circuit 30, and the ADC 35 of FIG. 1.

Referring to FIG. 2, the first pixel array 10 may be implemented in the first semiconductor chip 100. The second pixel array 20 may be implemented in the second semiconductor chip 200. The logic circuit 30 and the ADC 35 may be implemented in the third semiconductor chip 300.

The first pixel array 10 may convert incident light and generate an electrical signal. The second pixel array 20 may include unit pixels arranged in a matrix form along row directions and column directions. The second pixel array 20 may operate according to the control by the logic circuit 30. In detail, the logic circuit 30 may control a plurality of transistors included in the second pixel array 20. The plurality of transistors in the second pixel array 20 may control the electrical signals from the first pixel array 10, based on signals received from the logic circuit 30.

The logic circuit 30 may include a row driver 31 and a timing controller 32 and may be connected to the ADC 35. According to some example embodiments, the logic circuit 30 may generate readout signals using a global shutter method that simultaneously (e.g., at a same or about a same time) detects all units pixels, a flutter shutter method that adjusts the exposure time during which all unit pixels are simultaneously (e.g., at a same or about a same time) detected, a rolling shutter method that controls unit pixels on a row-by-row basis, a coded rolling shutter method, or the like.

The row driver 31 may control the second pixel array 20 in row units, according to the control by the timing controller 32. The row driver 31 may select at least one of the rows of the second pixel array 20 based on a row address. The row driver 31 may decode the row address and may be connected to a selection transistor SEL, a reset transistor RG, and a source follower transistor SF included in the second pixel array 20. The second pixel array 20 may be driven by a plurality of driving signals, such as a pixel selection signal, a reset signal, and a charge transfer signal, which are received from the row driver 31.

The ADC 35 may be connected to the second pixel array 20 through column lines COL. The ADC 35 may convert analog signals, which are received through the column lines COL from the second pixel array 20, into digital signals. The number of ADCs 35 may be determined based on the number of unit pixels arranged in one row and the number of column lines COL. There may be at least one ADC 35.

For example, the ADC 35 may include a reference signal generator REF, a comparator CMP, a counter CNT, and a buffer BUF. The reference signal generator REF may generate a ramp signal with a specific gradient and provide the ramp signal as a reference signal of the comparator CMP. The comparator CMP may compare the analog signal with the ramp signal from the reference signal generator REF and output comparison signals each having a transition point according to effective signal components. The counter CNT may generate a counting signal by performing a counting operation and provide the counting signal to the buffer BUF. The buffer BUF may include latch circuits respectively connected to the column lines COL and may latch the counting signal from the counter CNT onto each column in response to the transition of the comparison signal, thereby outputting the latched counting signal as data.

In some embodiments, the ADC 35 may further include correlated double sampling (CDS) circuits that are configured to perform CDS by calculating the difference between a reference voltage indicating a reset state of each unit pixel and an output voltage indicating a signal component corresponding to incident light and are further configured to output an analog sampling signal corresponding to an effective signal component. The CDS circuits may be connected to the column lines COL.

The timing controller 32 may control the operation timing of the row driver 31 and the ADC 35. The timing controller 32 may provide the timing signal and the control signal to the row driver 31 and the ADC 35. In more detail, the timing controller 32 may control the ADC 35, and the ADC 35 may provide data to the logic circuit 30 according to the control by the timing controller 32. In addition, the timing controller 32 may further include circuits that provide the logic circuit 30 with requests, commands, or addresses to enable the data of the ADC 35 to be stored in the memory cell array.

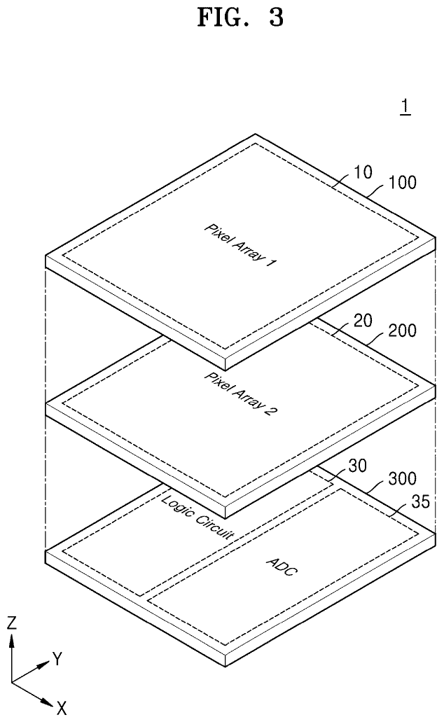

FIG. 3 is a perspective view three-dimensionally showing the first pixel array 10, the second pixel array 20, the logic circuit 30, and the ADC 35 of FIG. 1.

Referring to FIG. 3, in the image sensor 1, the first semiconductor chip 100 to the third semiconductor chip 300 may be sequentially stacked. FIG. 3 shows for convenience that the sizes of the first semiconductor chip 100, the second semiconductor chip 200, and the third semiconductor chip 300 are identical to each other, but one or more embodiments are not limited thereto. The sizes of the first semiconductor chip 100, the second semiconductor chip 200, and the third semiconductor chip 300 may vary. As described above, the first pixel array 10 may be arranged on the first semiconductor chip 100, and the second pixel array 20 may be arranged on the second semiconductor chip 200. The logic circuit 30 and the ADC 35 may be arranged on the third semiconductor chip 300.

In the first semiconductor chip 100 and the second semiconductor chip 200, a plurality of unit pixels may be arranged in a two-dimensional array on a two-dimensional plane. Although not shown, the first pixel array 10 may include a sensor array area and a pad area. The sensor array area may be located, for example, at the center of the first semiconductor chip 100, and the pad area may be located, for example, at the edge of the first semiconductor chip 100, but one or more embodiments are not limited thereto. In the sensor array area, active pixels configured to generate active signals by receiving light may be arranged. The second pixel array 20 may be configured to transmit a control signal to the sensor array area of the first pixel array 10. The second pixel array 20 may be configured to transmit an output signal of the unit pixel to the logic circuit 30 of the third semiconductor chip 300. The pad area may be configured such that the image sensor according to some embodiments may exchange electrical signals with an external device.

The logic circuit 30 may include circuits configured to process pixel signals from the unit pixels. The logic circuit 30 may receive an image signal from the ADC 35 and process the same.

The image sensor 1 according to some example embodiments may adjust capacitance in a floating diffusion area through a capacitor in a pixel array when a multi-conversion gain operation is performed in a 3-stack image sensor. Hereinafter, the structural characteristics are described in detail.

FIG. 4 is a circuit diagram showing a unit pixel including the first pixel array 10 and the second pixel array 20 of FIG. 1.

FIG. 4 is a circuit diagram showing a connection relationship between components included in a unit pixel PXa. The components in the unit pixel PXa may be divided into the first pixel array 10 and the second pixel array 20, and the components in the first pixel array 10 may be arranged on a different chip from the components in the second pixel array 20.

The first pixel array 10 may include a plurality of photoelectric conversion elements PD, a plurality of transfer transistors TG, a floating diffusion node FD, and a capacitor cap. The second pixel array 20 may include a reset transistor RG, a first conversion gain control transistor LRG, a second conversion gain control transistor HRG, a source follower transistor SF, and a selection transistor SEL. According to some example embodiments, the second pixel array 20 may be a pixel circuit configured to convert optical signals from the plurality of photoelectric conversion elements PD into electrical signals and output the electrical signals.

The first pixel array 10 may include the plurality of photoelectric conversion elements PD and the plurality of transfer transistors TG. According to some example embodiments, the number of photoelectric conversion elements PD may be the same as the number of transfer transistors TG. The photoelectric conversion elements PD may share the floating diffusion node FD. According to some example embodiments, the first pixel array 10 included in the unit pixel PXa may include eight photoelectric conversion elements PD. According to some example embodiments, the photoelectric conversion elements PD sharing the floating diffusion node FD may be arranged in a 2×4 array. The unit pixel PXa according to some example embodiments may be a pixel including eight photoelectric conversion elements PD arranged in a 2×4 array.

The photoelectric conversion element PD may generate charges in proportion to the amount of external incident light. The photoelectric conversion elements PD may be coupled to the transfer transistors TG configured to transmit the generated and accumulated charges to the floating diffusion node FD. The floating diffusion node FD may be an area where charges are converted into voltages and may cumulatively store charges because of parasitic capacitance thereof. The charges accumulated in the floating diffusion node FD may be converted into voltages. In this case, the ratio, at which the charges accumulated in the floating diffusion node FD are converted into voltages, may be referred to as a conversion gain. The conversion gain may vary depending on the capacitance of the floating diffusion node FD. When the capacitance of the floating diffusion node FD increases, the conversion gain decreases, and when the capacitance of the floating diffusion node FD decreases, the conversion gain may increase.

An end of the transfer transistor TG may be connected to the photoelectric conversion element PD, while the other end thereof may be connected to the floating diffusion node FD. The transfer transistor TG may be formed as a transistor driven according to a specific bias (e.g., a transfer signal TX). That is, the transfer transistor TG may be configured to transmit the charges generated by the photoelectric conversion element PD to the floating diffusion node FD, according to the transfer signal TX. According to some example embodiments, the transfer transistor TG may have a vertical transfer gate (VTG) structure that may increase the transfer efficiency of photo charges, but one or more embodiments are not limited thereto.

The source follower transistor SF may amplify a change in the electrical potential of the floating diffusion node FD receiving charges from the photoelectric conversion element PD and may output the amplified change to an output line VOUT. When the source follower transistor SF is turned on, a specific electrical potential provided to a drain of the source follower transistor SF, for example, the power voltage VDD, may be transmitted to a drain area of the selection transistor SEL.

The selection transistor SEL may select unit pixels to be read on a row-by-row basis. The selection transistor SEL may be a transistor driven by a selection line configured to apply a certain bias (e.g., a row selection signal SX).

The reset transistor RG may periodically reset the floating diffusion node FD. The reset transistor RG may be a transistor driven by a reset line configured to apply a certain bias (e.g., a reset signal). When the reset transistor RG is turned on according to the reset signal RX, a certain electrical potential provided to the drain of the reset transistor RG, for example, the power voltage VDD, may be transmitted to the floating diffusion node FD.

The first conversion gain control transistor LRG and the second conversion gain control transistor HRG may be connected to the floating diffusion node FD in series. Depending on whether the first conversion gain control transistor LRG and the second conversion gain control transistor HRG are turned on or off, the capacitance of the floating diffusion node FD may change, and the conversion gains may be variously changed accordingly. According to some example embodiments, a multi-conversion gain mode operation by the first conversion gain control transistor LRG and the second conversion gain control transistor HRG may be possible. The multi-conversion gain mode operation may refer to an operation of controlling a conversion gain in multiple stages.

According to some example embodiments, the first pixel array 10 of the unit pixel PXa may include a capacitor cap connected between the first conversion gain control transistor LRG and the second conversion gain control transistor HRG. According to some example embodiments, the first conversion gain control transistor LRG and the second conversion gain control transistor HRG may be arranged in the second pixel array 20, and the capacitor cap may be arranged in the first pixel array 10. That is, the first conversion gain control transistor LRG and the second conversion gain control transistor HRG may be formed on different semiconductor chips from the capacitor cap.

According to some example embodiments, the capacitor cap may be a poly-insulator-poly (PIP) capacitor. According to another embodiment, the capacitor cap may be an MIM capacitor. The capacitor cap may be connected between the first conversion gain control transistor LRG and the second conversion gain control transistor HRG and may provide additional capacitance. According to some example embodiments, the capacitance of the capacitor cap may be in a range from about or exactly 10 fF to about or exactly 20 fF.

According to some example embodiments, as the area of the unit pixel decreases, the photoelectric conversion element PD, the transfer transistor TG, and the capacitor cap may be formed on the first semiconductor chip (100 of FIG. 1), and the first conversion gain control transistor LRG, the second conversion gain control transistor HRG, the reset transistor RG, the source follower transistor SF, and the selection transistor SEL may be formed on the second semiconductor chip (200 of FIG. 1).

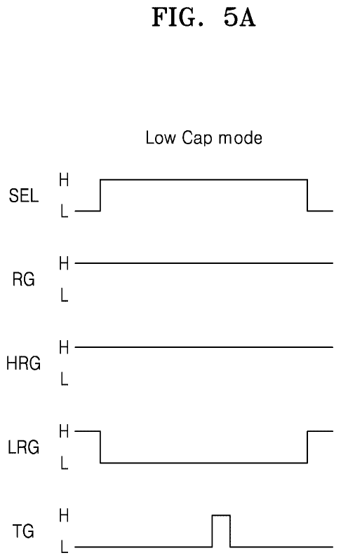

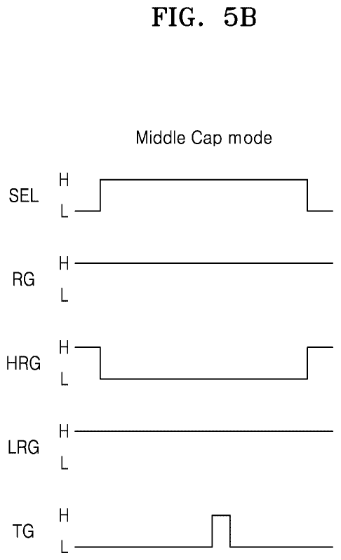

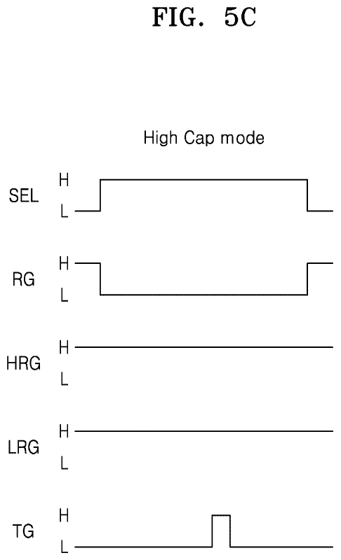

FIGS. 5A to 5C are timing diagrams showing timings of signals applied to adjust a multi-conversion gain in the circuit of FIG. 4.

FIGS. 5A to 5C are timing diagrams of signals respectively applied to the selection transistor SEL, the reset transistor RG, the second conversion gain control transistor HRG, the first conversion gain control transistor LRG, and the transfer transistor TG. When the signals applied to respective transistors are at high levels H, it may indicate that the corresponding transistors are turned on, and when the signals applied to respective transistors are at low levels L, it may indicate that the corresponding transistors are turned off. When the signal applied to the selection transistor SEL is at a high level H, a unit pixel including the selection transistor SEL may be selected, and thus, a pixel signal may be output.

FIG. 5A is a timing diagram to explain the timing of signals in a low capacitance mode, that is, a high conversion gain mode.

Referring to FIG. 5A, when the signal applied to the selection transistor SEL is at a high level H, the first conversion gain control transistor LRG may be at a low level L, while the second conversion gain control transistor HRG and the reset transistor RG may each be at the high level H. In this case, because the first conversion gain control transistor LRG connected to the floating diffusion node FD is turned off, the transistor connected to the floating diffusion node FD may also be turned off, resulting in a low capacitance of the floating diffusion node FD and thereby obtaining a high conversion gain.

FIG. 5B is a timing diagram to explain the timing of signals in a middle capacitance mode, that is, a middle conversion gain mode.

Referring to FIG. 5B, when the signal applied to the selection transistor SEL is at a high level H, the first conversion gain control transistor LRG may be at a high level H, the second conversion gain control transistor HRG may be at a low level L, and the reset transistor RG may be at a high level H. In this case, because the first conversion gain control transistor LRG connected to the floating diffusion node FD is turned on while the second conversion gain control transistor HRG is turned off, the capacitance of the floating diffusion node FD may increase due to the addition of the capacitances of the first conversion gain control transistor LRG and the capacitor cap located between the first conversion gain control transistor LRG and the second conversion gain control transistor HRG, compared to what is shown in FIG. 5A, resulting in a mid-level conversion gain.

FIG. 5C is a timing diagram to explain the timing of signals in a high capacitance mode, that is, a low conversion gain mode.

Referring to FIG. 5C, when the signal applied to the selection transistor SEL is at a high level H, the first conversion gain control transistor LRG and the second conversion gain control transistor HRG may each be at a high level H, while the reset transistor RG may be at a low level L. In this case, because the first conversion gain control transistor LRG and the second conversion gain control transistor HRG connected to the floating diffusion node FD are turned on while the reset transistor RG is turned off, the capacitance of the floating diffusion node FD may increase due to the addition of the capacitances of the first conversion gain control transistor LRG, the second conversion gain control transistor HRG, and the capacitor cap located between the first conversion gain control transistor LRG and the second conversion gain control transistor HRG, compared to what is shown in FIGS. 5A and 5B, resulting in a low conversion gain.

That is, by adjusting control signals applied to the first conversion gain control transistor LRG and the second conversion gain control transistor HRG, the conversion gains may be controlled in three stages such that the first conversion gain control transistor LRG and the second conversion gain control transistor HRG may operate in a multi-conversion gain mode. In addition, by using the capacitor cap connected between the first conversion gain control transistor LRG and the second conversion gain control transistor HRG, the capacitance may be additionally obtained in both the middle capacitance mode and the high capacitance mode. For example, according to some example embodiments, there may be an increase in speed, accuracy, resource efficiency and/or power efficiency of the device based on the above methods. Therefore, the improved devices and methods overcome the deficiencies of the conventional devices and methods while reducing resource consumption, and/or improving data accuracy, and resource allocation (e.g., latency).

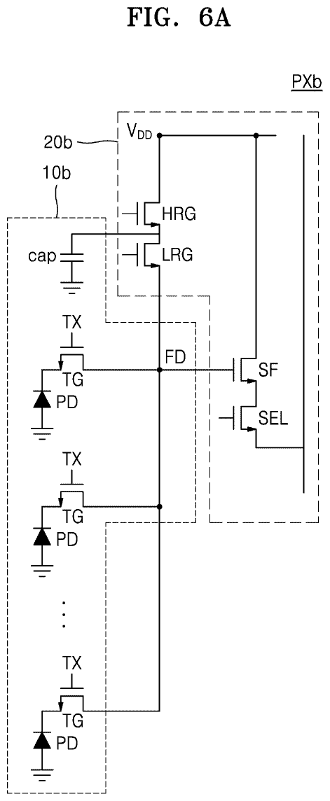

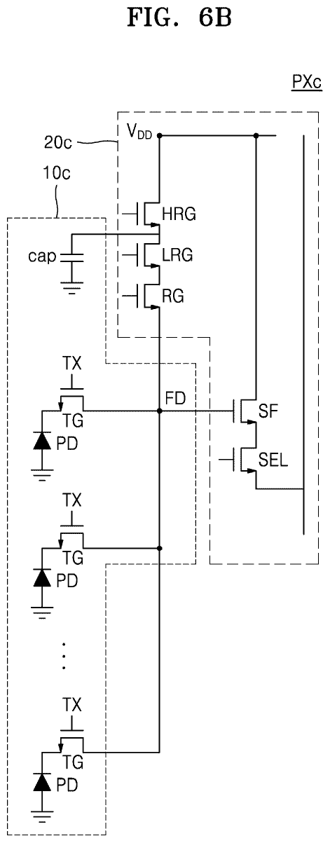

FIGS. 6A and 6B are circuit diagrams of unit pixels according to some example embodiments. In describing the circuit diagrams of FIGS. 6A and 6B, the components that are already described with reference to FIG. 4 are not described again.

Referring to FIG. 6A, components included in a unit pixel PXb may be divided into a first pixel array 10b and a second pixel array 20b, and the components included in the first pixel array 10b may be formed on different chips from the components included in the second pixel array 20b.

The second pixel array 20b of the unit pixel PXb of FIG. 6A may not include a reset transistor RG compared to the second pixel array 20 of the unit pixel PXa of FIG. 4. According to some example embodiments, the floating diffusion node FD may be connected to the first conversion gain control transistor LRG and the second conversion gain control transistor HRG, and the capacitor cap may be connected between the first conversion gain control transistor LRG and the second conversion gain control transistor HRG. Referring to FIG. 6A, the second conversion gain control transistor HRG may perform the function of the reset transistor RG, and the capacitance may be obtained by using the capacitor cap connected between the first conversion gain control transistor LRG and the second conversion gain control transistor HRG, thereby adjusting the capacitance of the floating diffusion node FD.

Components included in a unit pixel PXc of FIG. 6B may be divided into a first pixel array 10c and a second pixel array 20c, and the components included in the first pixel array 10c may be formed on different chips from the components included in the second pixel array 20c.

Referring to FIG. 6B, the second pixel array 20c may include the reset transistor RG connected to the floating diffusion node FD in series, the first conversion gain control transistor LRG, and the second conversion gain control transistor HRG. According to some example embodiments, the location where the reset transistor RG is connected may be different from that in the second pixel array 20 of the unit pixel PXa of FIG. 4. Referring to FIG. 6B, the reset transistor RG may be connected between the first conversion gain control transistor LRG and the floating diffusion node FD. The first conversion gain control transistor LRG may be connected to the second conversion gain control transistor HRG in series, and the capacitor cap may be connected between the first conversion gain control transistor LRG and the second conversion gain control transistor HRG.

FIGS. 6A and 6B are circuit diagrams of unit pixels according to some example embodiments and show two conversion gain control transistors and a capacitor connected therebetween, but one or more embodiments are not limited thereto. According to some example embodiments, the second pixel array may include three or more conversion gain control transistors, and in this case, the multi-conversion gain may be controlled in more stages than the three-stage control of the multi-conversion gain shown in FIGS. 5A and 5B. In addition, when the second pixel array includes three or more conversion gain control transistors, a capacitor cap may be connected between two adjacent conversion gain control transistors among the three or more conversion gain control transistors, and in this case, the capacitor cap may be formed in the first pixel array. According to another embodiment, when the second pixel array includes three or more conversion gain control transistors, two or more capacitors cap may be connected between three or more conversion gain control transistors. In this case, the two or more capacitors cap may also be formed in the first pixel array.

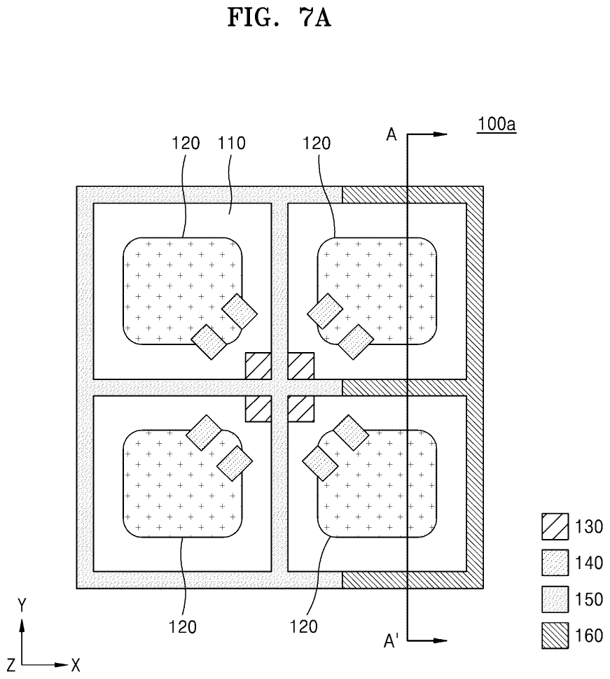

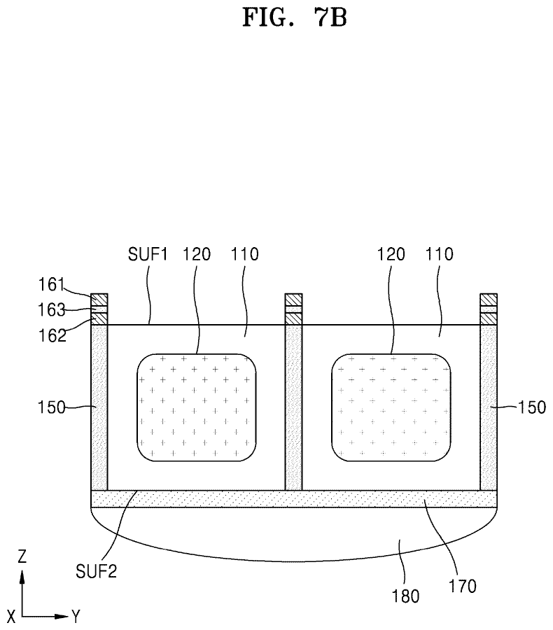

FIG. 7A is a plan view showing an arrangement of components of a first pixel array on a first semiconductor chip in the circuit diagram of FIG. 4. FIG. 7B is a cross-sectional view of the plan view of FIG. 7A, taken along a line A-A′ of FIG. 7A.

FIGS. 7A and 7B respectively are a plan view and a cross-sectional view of a first semiconductor chip 100a, illustrating the arrangement of components included in the first pixel array 10 among the components included in the circuit diagram of the unit pixel PXa of FIG. 4. FIG. 7A is a plan view of the first semiconductor chip 100a to explain the arrangement of four photoelectric conversion elements PD, four transfer transistors TG, a floating diffusion node FD, and a capacitor cap which are included in the first pixel array 10 of the unit pixel PXa of FIG. 4. While FIG. 4 shows that the first pixel array 10 of the unit pixel PXa includes eight photoelectric conversion elements PD and eight transfer transistors TG, FIG. 7A shows only four photoelectric conversion elements PD and four transfer transistors TG for convenience of explanation. That is, the plan view of FIG. 7A is a plan view showing the arrangement of some components of the first pixel array 10 of the unit pixel PXa.

Referring to FIGS. 7A and 7B, the first semiconductor chip 100a of the unit pixel according to some example embodiments may include a semiconductor substrate 110, a photoelectric conversion area 120 formed on the semiconductor chip 110, a floating diffusion area 130, a VTG 140, a deep trench isolation (DTI) structure 150, and a capacitor 160. According to some example embodiments, the first semiconductor chip 100a of the unit pixel may further include a color filter 170 and a microlens 180.

The semiconductor substrate 110 may have a first surface SUF1 and a second surface SUF2 opposite to the first surface SUF1. In some example embodiments, an image sensor including pixels may be a backside illumination (BSI) image sensor. In some example embodiments, the semiconductor substrate 110 may include a semiconductor layer formed through an epitaxial process. In some example embodiments, the semiconductor substrate 110 may be doped with impurities of a first conductivity type (e.g., a p-type).

The photoelectric conversion area 120 may be formed in the semiconductor substrate 110 and generate charges (e.g., photo charges) based on incident light. For example, electron-hole pairs may be generated in response to the incident light, and the photoelectric conversion area 120 may collect such electrons and holes. According to some example embodiments, the photoelectric conversion area 120 may include photodiodes, pinned photodiodes (PPD), phototransistors, photogates, or a combination thereof.

The floating diffusion area 130 may be spaced apart from the photoelectric conversion area 120 in the semiconductor substrate 110. In the floating diffusion area 130, the charges generated in the photoelectric conversion area 120 may be transmitted by the VTG 140 and stored. In some example embodiments, the floating diffusion area 130 may be doped with impurities of a second conductivity type (e.g., an n-type).

The VTG 140 or other transistors may be formed on the first surface SUF1 (e.g., the front surface) of the semiconductor substrate 110, and the incident light may reach the photoelectric conversion area 120 through the second surface SUF2 (e.g., the rear surface). The VTG 140 may be configured to form a transfer channel between the photoelectric conversion area 120 and the floating diffusion area 130 in response to a transfer signal to enable the charges generated in the photoelectric conversion area 120 to be transmitted to the floating diffusion area 130.

The first semiconductor chip 100a of the unit pixel may further include a DTI structure 150 formed to surround the photoelectric conversion area 120 to separate each photoelectric conversion area 120 from an adjacent photoelectric conversion area 120. The DTI structure 150 may extend to a certain depth from the first surface SUF1 of the semiconductor substrate 110 or may be formed by completely penetrating the semiconductor substrate 110 from the first surface SUF1 of the semiconductor substrate 110 to the second surface SUF2 thereof. In addition, in another embodiment, the DTI structure 150 may be formed by completely penetrating the semiconductor substrate 110 or to a certain depth from the second surface SUF2 of the semiconductor substrate 110. For example, the DTI structure 150 may include an arbitrary insulating material, such as silicon oxide (SiOx), silicon nitride (SiNx), and/or hafnium oxide (HfOx).

According to some example embodiments, the first semiconductor chip 100a of the unit pixel may include the capacitor 160 formed on the DTI structure 150. The capacitor 160 may include a first polysilicon member 161, a second polysilicon member 162, and an insulator member 163. Referring to FIG. 7B, the capacitor 160 may be a PIP capacitor. Referring to FIGS. 7A and 7B, the second polysilicon member 162 of the capacitor 160 may be formed on the DTI structure 150, and the insulator member 163 and the first polysilicon member 161 may be stacked on the second polysilicon member 162, thus forming the capacitor 160. As described, as the capacitor 160 is arranged on an upper portion of the DTI structure 150, additional capacitance may be achieved by utilizing the remaining portion on the upper plate of the stacked image sensor.

The color filter 170 may be formed on the second surface SUF2 of the semiconductor substrate 110 to correspond to the photoelectric conversion area 120. The color filter 170 may be included in a color filter array arranged in a matrix form. In some example embodiments, the color filter array may have a Bayer pattern including a red filter, a green filter, and a blue filter. In another embodiment, the color filter array may include a yellow filter, a magenta filter, and a cyan filter. In addition, the color filter array may additionally include a white filter. According to some example embodiments, an anti-reflection layer, at least one insulating layer, and the like may be formed between the color filter 170 and the second surface SUF2 of the semiconductor substrate 110.

The microlens 180 may be formed to correspond to the color filter 170 and the photoelectric conversion area 120. The microlens 180 may adjust a path of incident light to make the incident light entering the microlens 180 be concentrated into the photoelectric conversion area 120. Also, the microlens 180 may be included in a microlens array arranged in a matrix form.

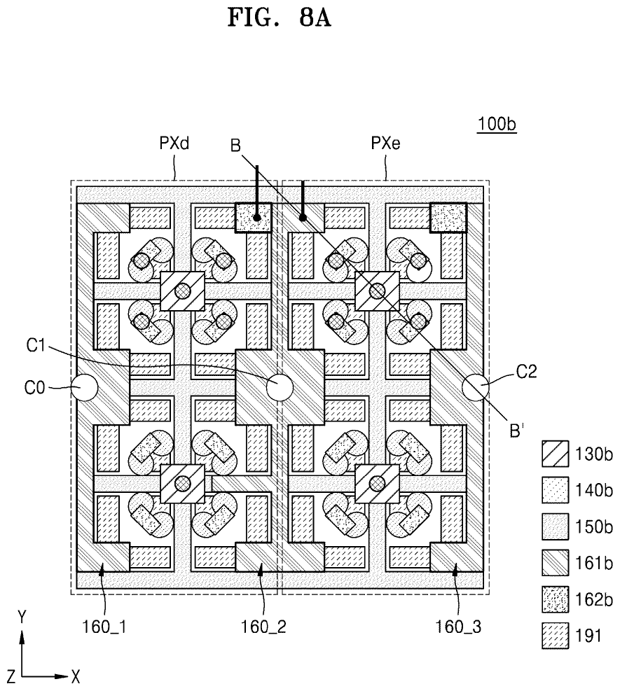

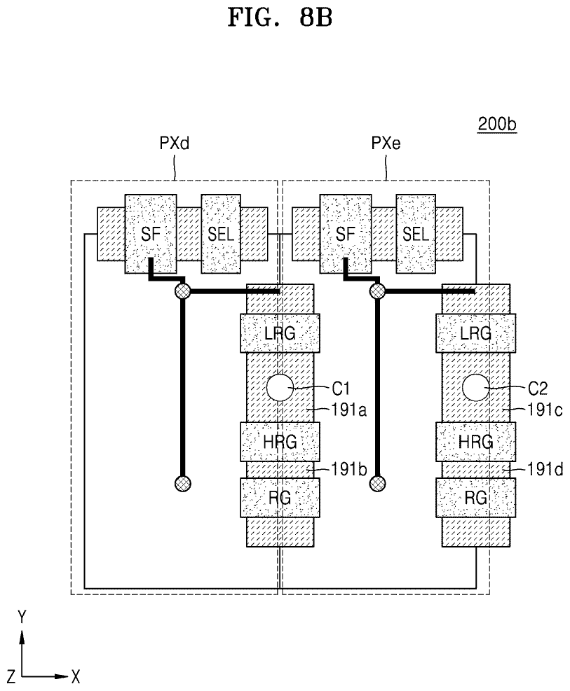

FIG. 8A is a plan view of unit pixels in a first semiconductor chip, according to some example embodiments.

FIG. 8A is a plan view of the first semiconductor chip 100b corresponding to first pixel arrays of a first unit pixel PXd and a second unit pixel PXe. According to some example embodiments, in the first semiconductor chip 100b, components included in the first pixel arrays of the first unit pixel PXd and the second unit pixel PXe may be arranged. The first unit pixel PXd may have the same or similar structure as the second unit pixel PXe. The first pixel arrays of the first unit pixel PXd and the second unit pixel PXe may each include eight photoelectric conversion areas, and each of the eight photoelectric conversion areas may be arranged in a 2×4 array. Because the first unit pixel PXd has the same or similar structure as the second unit pixel PXe, the description regarding the first unit pixel PXd may be equally applied to the second unit pixel PXe. According to some example embodiments, the components included in the first pixel arrays of the first unit pixel PXd and the second unit pixel PXe arranged in the first semiconductor chip 100b may correspond to the structure included in the first pixel array 10 of FIG. 4.

In the first semiconductor chip 100b of the first unit pixel PXd, a photoelectric conversion area (not shown), a floating diffusion area 130b, a VTG 140b, a DTI structure 150b, an upper polysilicon member 161b, and a lower polysilicon member 162b may be arranged. Also, silicon areas 191 may be formed in some portions of the first semiconductor chip 100b. According to some example embodiments, the silicon area 191 may be an active area.

Because the photoelectric conversion area, the floating diffusion area 130b, the VTG 140b, and the DTI structure 150b arranged in the first semiconductor chip 100b correspond to the photoelectric conversion area 120, the floating diffusion area 130, the VTG 140, and the DTI structure 150 described with reference to FIGS. 7A and 7B, repeated descriptions are omitted.

Referring to FIG. 8A, the lower polysilicon member 162b and the upper polysilicon member 161b may be arranged on the DTI structure 150b. Although not shown due to the characteristics of the plan view, an insulator member may be arranged between the lower polysilicon member 162b and the upper polysilicon member 161b. As the lower polysilicon member 162b, the upper polysilicon member 161b, and the insulator member therebetween may be combined, the first capacitor 160_1, the second capacitor 160_2, and the third capacitor 160_3 may be formed in the first semiconductor chip 100b.

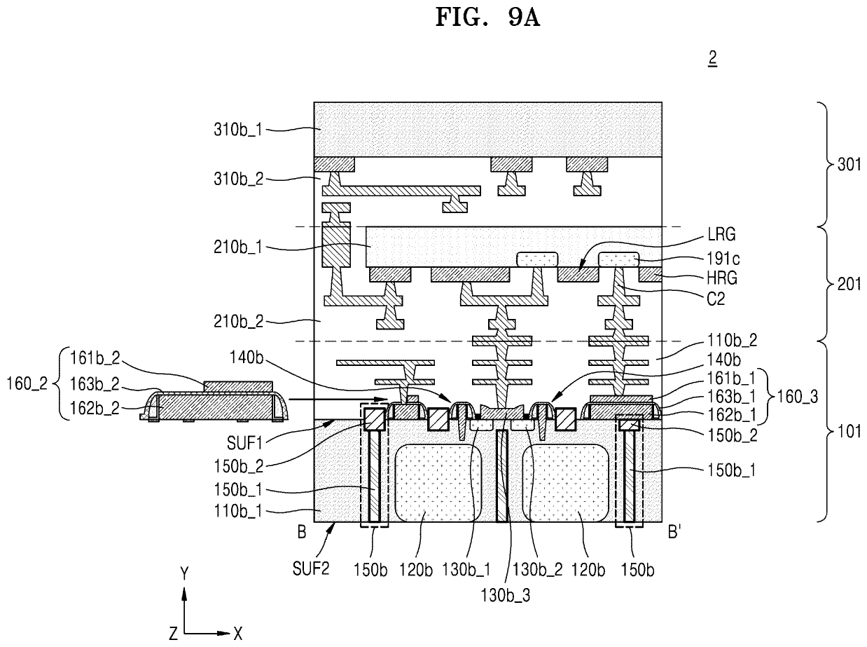

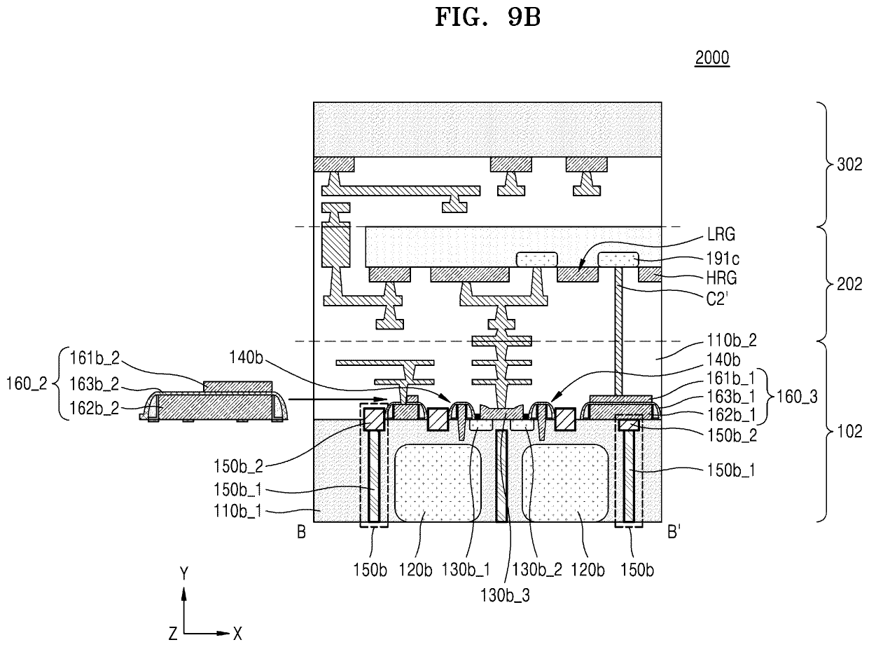

For example, in some example embodiments of FIGS. 7A and 7B the areas of the upper polysilicon member 161b and the lower polysilicon member 162b of the first capacitor 160_1, the second capacitor 160_2, and the third capacitor 160_3 may be different from those shown in some example embodiments of FIG. 8A. According to some example embodiments, the area of the lower polysilicon member 162b may be about or exactly the same as or greater than the area of the upper polysilicon member 161b. In FIG. 8A, under the region where the upper polysilicon member 161b is located, the lower polysilicon member 162b with an area corresponding to that of the above region may be formed. This will be described below in more detail with reference to FIG. 9A.

Referring to FIG. 8A, the upper polysilicon member 161b and the lower polysilicon member 162b may be combined, and the first capacitor 160_1, the second capacitor 160_2, and the third capacitor 160_3 may be formed. According to some example embodiments, a capacitor connected to correspond to the first unit pixel PXd may be the second capacitor 160_2, and a capacitor connected to correspond to the second unit pixel PXe may be the third capacitor 160_3. The first capacitor 160_1 may be a capacitor connected to correspond to a unit pixel arranged on the side surface of the first unit pixel PXd.

Referring to FIG. 8A, each unit pixel may include one capacitor, and in a plan view, each capacitor may be arranged not only on an upper portion of the corresponding unit pixel but also on an upper portion of an adjacent unit pixel. According to some example embodiments, the second capacitor 160_2 may be a capacitor corresponding to the first unit pixel PXd, but may be arranged to overlap the upper portion of the second unit pixel PXe.

Referring to FIG. 8A, the first capacitor 160_1, the second capacitor 160_2, and the third capacitor 160_3 may be connected to vertical contacts C0, C1, and C2, respectively. According to some example embodiments, the first capacitor 160_1 may be connected to the vertical contact C0, the second capacitor 160_2 may be connected to the vertical contact C1, and the third capacitor 160_3 may be connected to the vertical contact C2. The vertical contacts C0, C1, and C2 may extend in the Z-axis direction and may electrically connect the first semiconductor chip 100b to a second semiconductor chip 200b.

FIG. 8B is a plan view of unit pixels in a second semiconductor chip, according to some example embodiments.

FIG. 8B is a plan view of the second semiconductor chip 200b corresponding to the first unit pixel PXd and the second unit pixel PXe. According to some example embodiments, in the second semiconductor chip 200b, components included in second pixel arrays of the first unit pixel PXd and the second unit pixel PXe may be arranged. The first unit pixel PXd may have the same or similar structure as the second unit pixel PXe. Because the first unit pixel PXd and the second unit pixel PXe have the same or similar structures, the description regarding the first unit pixel PXd may be equally applied to the second unit pixel PXe. According to some example embodiments, the components included in the second pixel arrays of the first unit pixel PXd and the second unit pixel PXe arranged in the second semiconductor chip 200b may correspond to the structure of the second pixel array 20 of FIG. 4.

In the second semiconductor chip 200b of the first unit pixel PXd, a source follower transistor SF, a selection transistor SEL, a first conversion gain control transistor LRG, a second conversion gain control transistor HRG, and a reset transistor RG may be arranged. The source follower transistor SF, the selection transistor SEL, the first conversion gain control transistor LRG, the second conversion gain control transistor HRG, and the reset transistor RG of FIG. 8B may refer to gates of respective transistors.

Referring to FIG. 8B, the first conversion gain control transistor LRG, the second conversion gain control transistor HRG, and the reset transistor RG may be connected in series, the first conversion gain control transistor LRG and the second conversion gain control transistor HRG may share active areas 191a and 191c, and the second conversion gain control transistor HRG and the reset transistor RG may share active areas 191b and 191d. According to some example embodiments, the vertical contacts C1 and C2 may be connected between the first conversion gain control transistor LRG and the second conversion gain control transistor HRG and may correspond to the vertical contacts C1 and C2 of the first semiconductor chip 100b.

Therefore, the area between the first conversion gain control transistor LRG and the second conversion gain control transistor HRG and the second capacitors 160_2 and the third capacitor 160_3 of the first semiconductor chip 100b may be electrically connected through the vertical contacts C1 and C2 formed between the first conversion gain control transistor LRG and the second conversion gain control transistor HRG.

FIG. 9A is a cross-sectional view of the plan view of FIG. 8A, taken along a line B-B′. According to some example embodiments, the plan view of FIG. 8A shows the first semiconductor chip 100b, but for clear understanding, FIGS. 9A and 9B respectively are a cross-sectional view of a first semiconductor chip and a cross-sectional view of a second semiconductor chip and a third semiconductor chip stacked on the first semiconductor chip.

FIG. 9A is a cross-sectional view of an image sensor 2 in which a first semiconductor chip 101, a second semiconductor chip 201, and a third semiconductor chip 301 are sequentially stacked. According to some example embodiments, the first semiconductor chip 101 may be an upper plate, the second semiconductor chip 201 may be a middle plate, and the third semiconductor chip 301 may be a lower plate. In the drawing, it is shown that the first semiconductor chip 101 is formed at the lowest part, but it is only for convenience of explanation. The upper plate of the stacked image sensor 2 may be the first semiconductor chip 101. That is, the actual stacked image sensor 2 may be formed as the third semiconductor chip 301, the second semiconductor chip 201, and the first semiconductor chip 101 are sequentially stacked. According to some example embodiments, the first semiconductor chip 101 of FIG. 9A may correspond to the first semiconductor chip 100 of FIG. 3, the second semiconductor chip 201 of FIG. 9A may correspond to the second semiconductor chip 200 of FIG. 3, and the third semiconductor chip 301 of FIG. 9A may correspond to the third semiconductor chip 300 of FIG. 3.

The first semiconductor chip 101 may include a first semiconductor substrate 110b_1 and a first insulating layer 110b_2 arranged on the first semiconductor substrate 110b_1. The second semiconductor chip 201 may include a second semiconductor substrate 210b_1 and a second insulating layer 210b_2 arranged under the second semiconductor substrate 210b_1. The third semiconductor chip 301 may include a third semiconductor substrate 310b_1 and a third insulating layer 310b_2 arranged under the third semiconductor substrate 310b_1. In the present specification, the first semiconductor substrate 110b_1, the second semiconductor substrate 210b_1, and the third semiconductor substrate 310b_1 may each be a substrate including a semiconductor such as silicon. According to some example embodiments, the first semiconductor substrate 110b_1, the second semiconductor substrate 210b_1, and the third semiconductor substrate 310b_1 may each be a silicon single-crystal substrate or a silicon on insulator (SOI) substrate. In the present specification, the first insulating layer 110b_2, the second insulating layer 210b_2, and the third insulating layer 310b_2 may have, for example, a single-layer structure or a multi-layer structure including at least one of a silicon oxide layer, a silicon oxynitride layer, a silicon nitride layer, and a porous insulating layer.

Although not shown in FIG. 9A, a color filter and a microlens may be arranged under the first semiconductor substrate 110b_1. The first semiconductor substrate 110b_1 may include a photoelectric conversion area 120b corresponding to photodiodes. The first semiconductor substrate 110b_1 may include a DTI structure 150b separable from another pixel area. According to some example embodiments, the DTI structure 150b may be a structure formed as a DTI area 150b_1 is connected to an STI area 150b_2. The STI area 150b_2 may be an area formed for electrical isolation between elements on the surface on which the first semiconductor substrate 110b_1 contacts the first insulating layer 110b_2, and the DTI area 150b_1 may be an area penetrating the first semiconductor substrate 110b_1. According to some example embodiments, the DTI area 150b_1 may be an area contacting a second surface SUF2 of the first semiconductor substrate 110b_1 and separated from a first surface SUF1 thereof.

Floating diffusion areas 130b_1 and 130b_2 may be formed in the first semiconductor substrate 110b_1, and a VTG 140b may be formed in a recess area penetrating the first semiconductor substrate 110b_1. According to some example embodiments, a floating connection area 130b_3 connecting the floating diffusion areas 130b_1 and 130b_2 corresponding to adjacent photoelectric conversion areas 120b may be formed on the first insulating layer 110b_2. The floating connection area 130b_3 may be a material including polysilicon and may electrically connect the floating diffusion areas 130b_1 and 130b_2. According to some example embodiments, in the first semiconductor chip 101, the floating connection area 130b_3, a second capacitor 160_2, and a third capacitor 160_3 may be arranged. According to some example embodiments, the floating connection area 130b_3, a first polysilicon member 161b_2 and a second polysilicon member 162b_2 of the second capacitor 160_2, and a first polysilicon member 161b_1 and a second polysilicon member 162b_1 of the third capacitor 160_3 may include the same or similar materials. As described below, the floating connection area 130b_3, the second capacitor 160_2, and the third capacitor 160_3 may be simultaneously (e.g., at a same or about a same time) formed through a single process.

Referring to FIG. 9A, the second capacitor 160_2 and the third capacitor 160_3 may be arranged on the DTI structure 150b. The second capacitor 160_2 may include the first polysilicon member 161b_2, the second polysilicon member 162b_2, and an insulator member 163b_2, and the third capacitor 160_3 may include the first polysilicon member 161b_1, the second polysilicon member 162b_1, and an insulator member 163b_1. As described above with reference to FIG. 8A, the second capacitor 160_2 and the third capacitor 160_3 may be arranged on the upper portion of the DTI structure 150b, but within the range in which adjacent unit pixels are shared in a plan view, the areas of the second polysilicon members 162b_1 and 162b_2 may be formed. In other words, the areas of the second polysilicon members 162b_1 and 162b_2 contacting the upper portion of the DTI structure 150b are not limited to the cross-sectional area of the DTI structure 150b and may extend to the surface of an adjacent unit pixel within the range in which the second polysilicon members 162b_1 and 162b_2 do not interfere with peripheral transistors.

Referring to FIG. 9A, the area of the first polysilicon member 161b_2 of the second capacitor 160_2 may be different from that of the second polysilicon member 162b_2 of the second capacitor 160_2, and the area of the first polysilicon member 161b_1 of the third capacitor 160_3 may be the same or similar as that of the second polysilicon member 162b_1 of the third capacitor 160_3. According to some example embodiments, the first polysilicon member and the second polysilicon member may be materials including polysilicon, and the insulator member may be a material including SiO₂ and/or HfO₂. According to some example embodiments, the insulator member may include oxide, High-k (HfO₂), and/or the like.

The second capacitor 160_2 and the third capacitor 160_3 may be formed on the first insulating layer 110b_2 formed on the upper portion of the first semiconductor substrate 110b_1, and as the area, where the second capacitor 160_2 and the third capacitor 160_3 are formed, is located above the upper portion of the DTI structure 150b, the remaining portions of the first insulating layer 110b_2 may be effectively utilized, and the complexity of wiring may decrease.

Through the vertical contact C2 penetrating the second insulating layer 210b_2 of the second semiconductor chip 201, an active area 191c, which is shared by the first conversion gain control transistor LRG and the second conversion gain control transistor HRG formed on the second semiconductor chip 201, may be electrically connected to the third capacitor 160_3.

The second insulating layer 210b_2 of the second semiconductor chip 201 may include a plurality of metal pads and additional vertical contacts, and the vertical contacts formed at different locations may be vertically connected through the metal pads. According to some example embodiments, the second insulating layer 210b_2 of the second semiconductor chip 201 may include gates of a source follower transistor, a selection transistor, a first conversion gain control transistor, a second conversion gain control transistor, and a reset transistor, and the active areas of the aforementioned transistors may be included in the second semiconductor substrate 210b_1. For convenience of explanation, other transistors, excluding the first conversion gain control transistor and the second conversion gain control transistor, are omitted from the drawings.

The third semiconductor chip 301 may include a third semiconductor substrate 310b_1 and a third insulating layer 310b_2, and the third insulating layer 310b_2 may include a plurality of metal pads and vertical contacts and gates of the transistors. According to some example embodiments, the logic circuit 30 and the ADC 35 of FIG. 1 may be included in the third semiconductor chip 301.

FIG. 9B is a cross-sectional view of the plan view of FIG. 8A, taken along a line B-B′.

In describing some example embodiments of FIG. 9B, the components that are already described with reference to FIG. 9A are not described again. FIG. 9B shows a first semiconductor chip 102, a second semiconductor chip 202, and a third semiconductor chip 302 that are sequentially stacked.

Referring to FIG. 9B, an image sensor 2000 may further include a deep contact C2′ for connecting the active areas 191c, which are located on different layers, to a third capacitor 160_3. According to some example embodiments, the deep contact C2′ may be a vertical contact vertically extending in a third direction from a first polysilicon member 161b_1 of the third capacitor 160_3, that is, the Z-axis direction. The deep contact C2′ may penetrate a first insulating layer 110b_2 and a second insulating layer 210b_2.

According to some example embodiments of FIGS. 9A and 9B, the second capacitor 160_2 and the third capacitor 160_3 may be arranged to obtain capacitance of a floating diffusion area in the first semiconductor chips 101 and 102 and may be formed on the upper portion of the DTI structure 150b. In addition, the second capacitor 160_2 and the third capacitor 160_3 may be electrically connected between the first conversion gain control transistor LRG and the second conversion gain control transistor HRG through the vertical contact C2 or the deep contact C2′ extending in the Z-axis direction, the first conversion gain control transistor LRG and the second conversion gain control transistor HRG being formed on different layers.

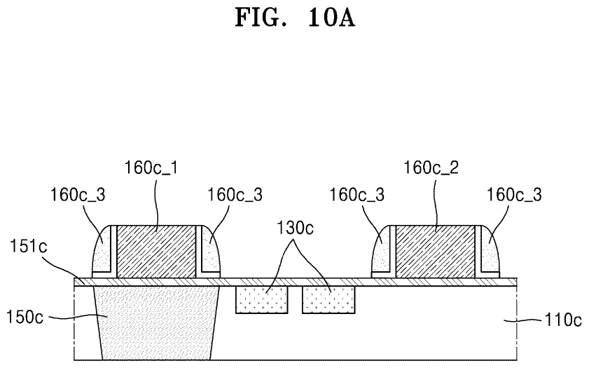

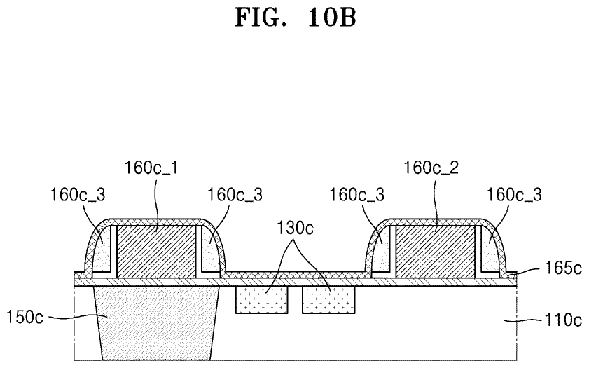

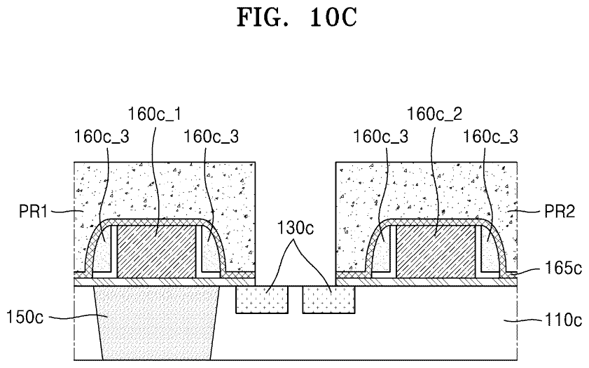

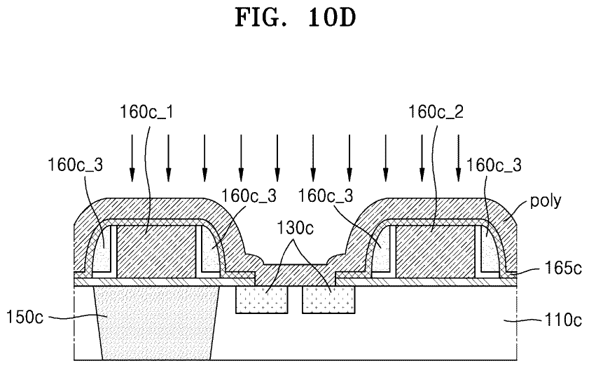

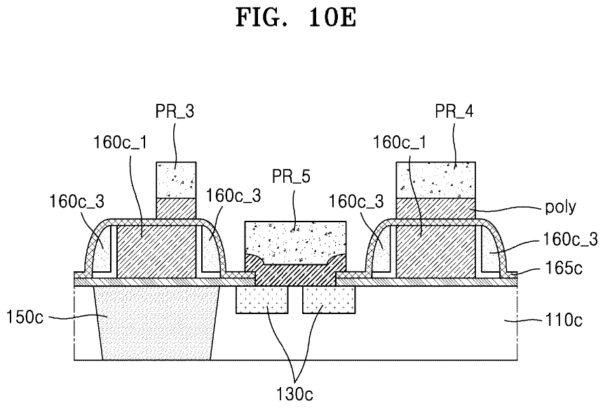

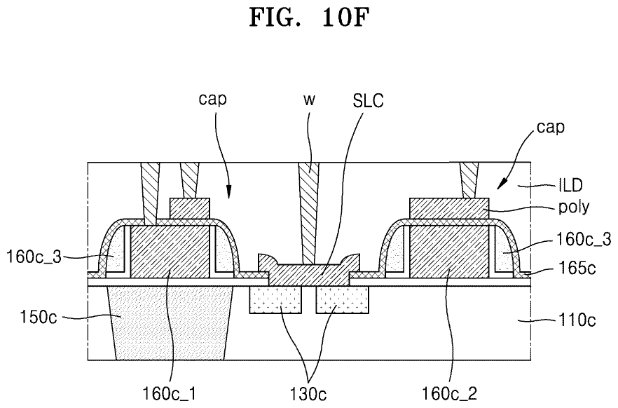

FIGS. 10A to 10F are cross-sectional views to explain the generation of a capacitor in a first semiconductor chip, according to some example embodiments.

Referring to FIG. 10A, floating diffusion areas 130c and an STI area 150c may be formed in a first substrate 110c, and an insulating layer 151c covering the floating diffusion areas 130c and the STI area 150c may be formed on the surface of the first substrate 110c. Polysilicon members 160c_1 and 160c_2 may be formed on the insulating layer 151c. According to some example embodiments, gate spacers 160c_3 may be formed on both sides of each of the polysilicon members 160c_1 and 160c_2.

Referring to FIG. 10B, an oxide layer 165c covering the polysilicon members 160c_1 and 160c_2 and the gate spacers 160c_3 may be deposited.

Referring to FIG. 10C, to form a floating connection area for connecting the floating diffusion areas 130c, photoresist PR_1 and PR_2 may be applied over the polysilicon members 160c_1 and 160c_2 and the gate spacers 160c_3 and then etched accordingly. According to some example embodiments, the etching may be performed by a wet etching process or a dry etching process.

Referring to FIG. 10D, the photoresist PR_1 and PR_2 may be removed, and polysilicon poly may be additionally deposited. Through this process, it may be identified that deposition is performed in the stated order of polysilicon-insulator-polysilicon.

Referring to FIG. 10E, photoresist PR_3, PR_4, and PR_5 may be applied to remove unnecessary polysilicon and then be etched accordingly. According to some example embodiments, the etching may be performed by a wet etching process or a dry etching process.

Referring to FIG. 10F, the photoresist PR_3, PR_4, and PR_5 may be removed, and a contact w and an interlayer insulating layer ILD may be formed. Through the above processes, a PIP capacitor cap and a floating connection area SLC for connecting the floating diffusion areas 130c may be formed. According to the processes stated above, capacitors cap may be generated alongside the floating connection area SLC for connecting the floating diffusion areas 130c, resulting in cost-effectiveness in the process.

According to the Comparative Example, there is a desire to connect adjacent unit pixels to obtain capacitance of a floating diffusion area, and as the connections increase, image quality may deteriorate due to defects. According to some example embodiments as disclosed herein, by forming a capacitor on an upper plate in a 2-layer pixel structure, capacitances of floating diffusion areas for increasing a dynamic range within a unit pixel may be adjusted using the capacitor on the upper plate, enabling a decrease in wiring complexity.

Any or all of the elements described with reference to the figures may communicate with any or all other elements described with reference to figures. For example, any element may engage in one-way and/or two-way and/or broadcast communication with any or all other elements in the figures, to transfer and/or exchange and/or receive information such as but not limited to data and/or commands, in a manner such as in a serial and/or parallel manner, via a bus such as a wireless and/or a wired bus (not illustrated). The information may be in encoded various formats, such as in an analog format and/or in a digital format.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As described herein, any electronic devices and/or portions thereof according to any of the example embodiments may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods performed by some or all of any devices, systems, modules, units, controllers, circuits, architectures, and/or portions thereof according to any of the example embodiments, and/or any portions thereof.

While the inventive concepts have been particularly shown and described with reference to some example embodiments thereof, it will be understood that various changes in form and details may be made therein without departing from the spirit and scope of the following claims.

What is claimed is:

1. A stacked image sensor comprising:
a first pixel array comprising a plurality of photoelectric conversion elements sharing a floating diffusion node; and
a second pixel array configured to convert optical signals from the plurality of photoelectric conversion elements into electrical signals and output the electrical signals,
the second pixel array comprising
a first conversion gain control transistor connected to the floating diffusion node; and
a second conversion gain control transistor connected to the first conversion gain control transistor in series, and
the first pixel array further comprises a capacitor connected between the first conversion gain control transistor and the second conversion gain control transistor.

2. The stacked image sensor of claim 1, wherein the capacitor comprises a Poly-insulator-Poly capacitor.

3. The stacked image sensor of claim 1, wherein a number of the plurality of photoelectric conversion elements is eight.

4. The stacked image sensor of claim 1, further comprising a reset transistor connected to the second conversion gain control transistor in series.

5. The stacked image sensor of claim 1, further comprising a reset transistor connected between the first conversion gain control transistor and the floating diffusion node.

6. The stacked image sensor of claim 1, wherein the first pixel array and the second pixel array are on different semiconductor chips.

7. A stacked image sensor comprising:
a first semiconductor chip comprising at least one photoelectric conversion area, at least one floating diffusion area, at least one transfer transistor configured to transmit charges in the at least one photoelectric conversion area to the at least one floating diffusion area, and a deep trench isolation structure configured to separate each of the at least one photoelectric conversion area; and
a second semiconductor chip including a pixel circuit, the pixel circuit configured to convert an optical signal from the at least one photoelectric conversion area into an electrical signal and output the electrical signal, and
the first semiconductor chip including a capacitor formed on the deep trench isolation structure, and the capacitor configured to adjust a conversion gain in the at least one floating diffusion area.

8. The stacked image sensor of claim 7, wherein the capacitor comprises a Poly-insulator-Poly capacitor.

9. The stacked image sensor of claim 7, wherein the second semiconductor chip including a first conversion gain control transistor and a second conversion gain control transistor, the first and second conversion gain control transistors configured to adjust capacitance of the at least one floating diffusion area.

10. The stacked image sensor of claim 9, wherein the capacitor is electrically connected to an active area shared by the first conversion gain control transistor and the second conversion gain control transistor.

11. The stacked image sensor of claim 7, wherein
the capacitor comprises
a first polysilicon member;
a second polysilicon member; and
an insulator member located between the first polysilicon member and the second polysilicon member, and
an area of the first polysilicon member is different from an area of the second polysilicon member.

12. The stacked image sensor of claim 11, wherein
the first semiconductor chip includes a floating connection area, the floating connection area configured to connect the at least one floating diffusion area, and
the floating connection area, the first polysilicon member, and the second polysilicon member comprise a same material.

13. A stacked image sensor comprising:
a first unit pixel comprising a first pixel array and a second pixel array, the first pixel array comprising a plurality of photoelectric conversion elements sharing a floating diffusion node, and the second pixel array configured to convert optical signals from the plurality of photoelectric conversion elements into electrical signals and output the electrical signals; and
a second unit pixel comprising a first pixel array and a second pixel array, the first pixel array of the second unit pixel comprising a plurality of photoelectric conversion elements sharing a floating diffusion node, and the second pixel array of the second unit pixel configured to convert optical signals from the plurality of photoelectric conversion elements into electrical signals and output the electrical signals,
the first pixel array of the first unit pixel and the first pixel array of the second unit pixel are in a first semiconductor chip, and the second pixel array of the first unit pixel and the second pixel array of the second unit pixel are in a second semiconductor chip,
the second pixel array of the first unit pixel and the second pixel array of the second unit pixel each comprise a first conversion gain control transistor connected to the floating diffusion node and a second conversion gain control transistor connected to the first conversion gain control transistor in series, and
the first pixel array of the first unit pixel and the first pixel array of the second unit pixel each further comprise a capacitor configured to respectively adjust a conversion gain of the floating diffusion node.

14. The stacked image sensor of claim 13, wherein the capacitor comprises a Poly-insulator-Poly capacitor.

15. The stacked image sensor of claim 13, wherein the capacitor is electrically connected to an active area shared by the first conversion gain control transistor and the second conversion gain control transistor.

16. The stacked image sensor of claim 15, wherein the active area is electrically connected to the capacitor through a deep contact.

17. The stacked image sensor of claim 13, wherein
the capacitor comprises
a first polysilicon member;
a second polysilicon member; and
an insulator member between the first polysilicon member and the second polysilicon member, and
an area of the first polysilicon member is different from an area of the second polysilicon member.

18. The stacked image sensor of claim 17, wherein an upper portion of a deep trench isolation structure contacts the second polysilicon member, and the deep trench isolation structure is configured to separate the plurality of photoelectric conversion elements.

19. The stacked image sensor of claim 17, wherein the capacitor includes the second polysilicon member in an area shared with the first unit pixel and the second unit pixel in two dimensions.

20. The stacked image sensor of claim 13, wherein a number of the plurality of photoelectric conversion elements is eight.
